(19) United States
(12) Patent Application Publication
(10) Pub. No.: US 2025/0062107 A1
(43) Pub. Date: Feb. 20, 2025

(54) METHOD AND SYSTEM FOR MONITORING RADICAL SPECIES FLUX OF PLASMA

(71) Applicant: APPLIED MATERIALS, INC., Santa Clara, CA (US)

(72) Inventors: Martin Hilkene, Santa Clara, CA (US); Tobin Kaufman-Osborn, Santa Clara, CA (US); Yunil Cho, San Jose, CA (US)

(21) Appl. No.: 18/234,169

(22) Filed: Aug. 15, 2023

(51) Int. Cl. H01J 37/32; H01J 37/244

(52) U.S. Cl. CPC H01J 37/32926; H01J 37/244; H01J 37/3288; H01J 2237/24585; H01J 2237/24592

(57) ABSTRACT

A method of monitoring a plasma-based process in a process chamber includes measuring a first temperature at a first location associated with a process chamber during a plasma-based process; and determining a value representative of a first radical species flux associated with the plasma-based process based on the first temperature. The method includes a trained machine learning model to determine if a value representative of a radical species flux satisfies a radical species flux drift threshold.

### TECHNICAL FIELD

Embodiments of the present disclosure relate to manufacturing. In particular, the present disclosure relates to a system and a method for monitoring the radical species flux of a plasma.

### BACKGROUND

Traditionally, manufacturing recipes performed by process chambers are static recipes that are applied mechanically and without reacting to in-situ conditions. Additionally, determinations of when to perform maintenance on process chambers and when to bring process chambers back into service are made statically based on set schedules and predetermined recipes. Process chambers generally do not have any autonomy or ability to make their own decisions with regards to process recipes, maintenance, tool qualification, and so on.

A processing chamber, i.e. a plasma chamber, is ideally kept in a steady state to maintain process uniformity of substrates (e.g., wafers) that are processed in the chambers. The steady state conditions are dependent on maintaining good chamber health. The chamber health may include parameters such as an accurate power input, functional heat exchanges and other thermal components, no leaks, and the like.

Currently, it is difficult to monitor the processing environment of the chamber to ensure that everything is working as desired. Instead, metrology of the processed substrates is used to determine when the chamber experiences an excursion from the desired steady state condition. This can result in misprocessed substrates, which increases costs and reduces throughput. Thus, there is a need for an improved method to monitor the process chamber.

### SUMMARY

Described herein is a method for monitoring a processing chamber. In some embodiments, the method may include measuring a first temperature at a first location associated with a process chamber during a plasma-based process; and determining a value representative of a first radical species flux associated with the plasma-based process based on the first temperature.

In some embodiments, a method may include receiving or generating a training data set associated with a plasma-based process performed at a process chamber, the training data set including a plurality of data items. Each data item of the plurality of the training data items may include a temperature measurement generated by a temperature sensor at a location associated with the process chamber and a label indicating a state of the process chamber. The method further includes training a machine learning model using the training data set to generate a trained machine learning model trained to receive a temperature measurement generated by the temperature sensor at the location and to determine a value representative of a radical species flux with the plasma-based process based on the temperature.

In some embodiments, a system includes a process chamber configured to perform a plasma-based process; a temperature sensor at a first location associated with the process chamber, the temperature sensor to generate one or more temperature measurements during the plasma-based process; and a computing device. The computing device is configured to receive a first temperature measurement generated by the temperature sensor during the plasma-based process; and to determine a value representative of a first radical species flux associated with the plasma-based process based on the first temperature.

Numerous other features are provided in accordance with these and other aspects of the disclosure. Other features and aspects of the present disclosure will become more fully apparent from the following detailed description, the claims, and the accompanying drawings.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1A is a plan view illustration of a processing tool with a remote plasma source (RPS) with indirect process monitoring sensors, in accordance with an embodiment;

FIG. 1B is a plan view illustration of a processing tool with an RPS and a plurality of indirect process monitoring sensors, in accordance with an additional embodiment;

FIG. 2 depicts a sectional view of a processing tool including a process chamber in accordance with an embodiment;

FIG. 3 is a flow chart for a method of monitoring a process chamber, according to an embodiment.

FIG. 4 is a flow chart for a method of performing actions by a process tool and/or substrate processing system, according to another embodiment.

FIG. 5 is a flow chart for a method of monitoring a process chamber and determining when to perform maintenance on the process chamber.

FIG. 6 is a flow chart for a method of automatically determining when to perform maintenance on a process chamber, according to an embodiment.

FIG. 7 is a flow chart for a method of automatically determining when to return a process chamber back to service after maintenance has been performed, according to an embodiment.

FIG. 8 illustrates a diagrammatic representation of a machine in the example form of a computing device within which a set of instructions, for causing the machine to perform any one or more of the methodologies discussed herein, may be executed.

### DETAILED DESCRIPTION OF EMBODIMENTS

Embodiments described herein relate to a method and/or system to monitor an amount of flux (e.g., radical species flux) of a plasma during a plasma-based process. When a plasma-based process is performed, it is difficult to monitor radical species flux of the plasma. There are presently no robust solutions the enable monitoring a repeatability of radical species flux produced by a plasma source. While use of optical emission spectroscopy has been attempted for monitoring of radical species, such techniques are generally ineffective and expensive. The method and system described herein addresses these issues using a non-optical sensing means (e.g., by using non-optical sensors whose measurement values correlate to radical species flux concentrations) and allow for a method and system to detect an amount of radical species flux associated with a plasma-based process that is both effective an inexpensive. The system and method further enable detection of changing conditions of radical species flux, such as a radical flux drift. The method and system of the present disclosure is a low cost, non-optical technique and system that enables monitoring of the plasma health of either in-situ or remote plasma sources.

The method and system according to embodiments of the present disclosure utilize temperature sensors that may already be present in a process chamber and/or exhaust or foreline components associated with a process chamber to detect radical species flux. As the method and system utilize temperature sensors, it is easy and low cost to integrate into a process chamber. The inventors of the present disclosure have found that small changes in temperatures correlate to changes in a radical species flux. When there is a change in radical species flux, then one or more parameters of a plasma-based process (e.g., such as etch rate, deposition rate, film growth rate, etc.) will likely change as the density of the radicals in the process also changes.

In an embodiment, a method is provided including measuring a first temperature at a first location associated with a process chamber during a plasma-based process; and determining a value representative of a first radical species flux associated with the plasma-based process based on the first temperature. In some embodiments, the measured temperature is input into a trained machine learning model that has been trained to estimate a value associated with radical species flux based on temperature. The trained machine learning model may then output a current estimated value associated with radical species flux based on the temperature. In some embodiments, the machine learning model outputs an actual estimated radical species flux. In some embodiments, the value output by the trained machine learning model is proportional to radical species flux but does not indicate an actual amount of radical species flux. In some embodiments, the process chamber may have any chamber configuration as known in the art. For example, the chamber may be a plasma etch chamber, a plasma deposition chamber, etc., which may use a remote plasma source or an in-situ plasma source. In some embodiments, the plasma-based process may include plasma etching, plasma-assisted chemical vapor deposition (PECVD), plasma-enhanced atomic layer deposition, plasma etching, and so on.

In some embodiments, the first location at which the temperature sensor is placed may include or be an inlet to the process chamber through which a plasma flows during the plasma-based process. In some embodiments, the first location is a bend or restriction in a vacuum line that provides a plasma (e.g., from a remote plasma source) to a process chamber. In some embodiments, the first location is interior to a process chamber. In some embodiments, the first location is at an exhaust line of a process chamber. Other locations may also be used for the temperature sensor.

In some embodiments of the method, determining the value representative of the radical species flux includes inputting the temperature into a trained machine learning model that outputs the value representative of the radical species flux.

In embodiments, trained machine learning models are edge-based models that execute on the processing chamber themselves rather than on remote computing devices. Training of the machine learning models may be performed remotely, after which trained machine learning models may be transferred to the processing chamber, or may be performed on the processing chamber. Retraining or updating of training of the machine learning models may be performed periodically or continuously on the processing chamber. By having execution and/or training (including retraining) of the machine learning models to the processing chamber, latency between generation of sensor measurements and making decisions based on such sensor measurements can be significantly reduced. This improves an ability to make real-time decisions for process chambers. Additionally, moving the decision making to the processing chamber reduces an amount of data that is transmitted over a network, increases efficiency, and increases a speed with which decisions can be made. For example, a decision of when to stop an etch process can be made within seconds or fractions of a second from when sensor data that triggers such a decision is received in embodiments that include a machine learning model trained to detect an etch endpoint.

In some embodiments, the method may further include measuring a second temperature at a second location associated with the process chamber during the plasma-based process; and determining a second value representative of a second radical species flux associated with the plasma-based process based on the second temperature. In some embodiments, the second location may include an exhaust line of the process chamber.

In some embodiments, when the temperature at an inlet to a process chamber and/or a temperature of at an exhaust line of the process are stable (e.g., not changing or only minimally changing with time), the plasma flux may be stable. In some embodiments, when the temperature at an inlet of a process chamber is about the same as a temperature at an outlet of the process chamber, the process chamber may have reached a stable state, and may be ready for processing of substrates. In some embodiments, the locations of one or more temperature sensors whose measurements are used to determine radical species flux (e.g., at an inlet and/or exhaust line of the process chamber and/or surrounding areas) may include a catalytic material. In some embodiments, the temperature sensor may be mounted to a catalytic material. In other embodiments, the chamber component may be made from stainless steel, or nickel, or another catalytic material. In some embodiments, the locations of one or more temperature sensors relates to a location in which a radical species may impinge with that location and/or a bend in the process chamber. The catalytic material may include stainless steel, platinum, nickel, gold, and/or another material. The catalytic material may increase a reaction of radical species to a site at which a temperature sensor is located, increasing the sensitivity to detection of radical species flux. In some embodiments, the temperature sensor of the present disclosure may be a thermocouple, a resistance thermometer, a resistance temperature device, a thermistor, and/or other temperature sensor.

In some embodiments, the method may further include determining whether the determined value representative of the radical species flux satisfies a criterion. The method may further include scheduling maintenance responsive to determining that the value representative of the radical species flux satisfies the criterion.

In some embodiments, the plasma-based process is a seasoning process for a process chamber. In some embodiments of the method, measuring the temperature may be performed at a first time. The method may further include measuring a second temperature at the first location during the plasma-based process at a second time. The method may further include determining a second value representative of a second radical species flux based on the second temperature. The method may further include comparing the second value to the first value to identify a difference between the second value and the first value. The method may further include determining whether the difference between the second value and the first value satisfies a criterion. The method may further include stopping the seasoning process responsive to determining that the difference satisfies the criterion.

In another embodiment of the method, measuring the temperature is performed at a first time. The method may further include measuring a second temperature at the first location during a second plasma-based process at a second time, wherein the second plasma-based process is the same process as the plasma-based process. The method may further include determining a second value representative of a second radical species flux based on the second temperature. The method may further include comparing the second value to the first value to identify a difference between the second value and the first value. The method may further include determining whether the difference between the second value and the first value satisfies a criterion. The method may further include scheduling maintenance responsive to determining that the difference satisfies the criterion.

In some embodiments, the criterion may include a radical species flux drift threshold, and the criterion may be satisfied responsive to the difference meeting or exceeding the radical species flux drift threshold.

In another embodiment, an additional method is provided. The method includes receiving or generating a training data set associated with a plasma-based process performed at a process chamber in a known good condition. The training data set may include a plurality of data items, wherein each data item of the plurality of training data items may include a temperature measurement generated by a temperature sensor at a location associated with the process chamber and a label indicating a state of the process chamber. The method further includes training a machine learning model using the training data set to generate a trained machine learning model trained to receive a temperature measurement generated by the temperature sensor at the location and to determine a value representative of a radical species flux associated with the plasma-based process based on the temperature. Different machine learning models may be trained for processing of temperature measurements taken by different sensors at different locations.

In some embodiments, the machine learning model may be further trained to predict when a seasoning process performed on the process chamber after a maintenance event is complete based on the temperature. In embodiments, the machine learning model is trained based on data of one or more chambers in a known target state. The trained machine learning model may then be monitored until the sensors indicate that a signal is the same as the known target state within a tolerance (e.g., +/−10-20%). When the sensors match the trained sensor values within the specified tolerance, the conditioning or seasoning of the chamber may be complete. In another embodiment, the machine learning model may be further trained to predict when to perform maintenance associated with the process chamber based on the temperature.

In another embodiment, a system is provided. The system includes a process chamber configured to perform a plasma-based process. The system further includes a temperature sensor at a first location associated with the process chamber, wherein the temperature sensor is configured to generate one or more temperature measurements during the plasma-based process and a computing device. The computing device may be configured to receive a first temperature measurement generated by the temperature sensor during the plasma-based process and determine a value representative of a first radical species flux associated with the plasma-based process based on the first temperature. In some embodiments, the temperature sensor of the present disclosure may be a thermocouple, a resistance thermometer, a resistance temperature device, a thermistor, or another type of temperature sensor.

In yet another embodiment, a non-transitory computer-readable medium includes instructions that, when executed by a processor, cause the processor to perform operations including measuring a first temperature at a first location associated with a process chamber during a plasma-based process, and determining a value representative of a first radical species flux associated with the plasma-base process based on the first temperature.

Generally, embodiments disclosed herein are suitable for use with any processing tool that employs a plasma-based process. For example, embodiments are usable with semiconductor processing tools that employ plasma-based processes. Examples of processing tools that employ plasma-based processes include plasma etch reactors, plasma cleaners, deposition chambers that use plasma (e.g., CVD chambers, ion assisted deposition (IAD) chambers, ALD chambers, and so on). In some embodiments, the processing tool includes a remote plasma source (RPS). In some embodiments, the processing tool includes an in-situ plasma source. In one example, a processing tool is used for rapid thermal processing (RTP), such as an oxidation treatment, a plasma enhanced thermal oxidation, and/or nitridation process. In such embodiments, an array of heating lamps may be provided above a substrate. A reflector plate may be provided below the substrate in order to reflect thermal energy back towards the substrate. In an embodiment, an RPS or in situ plasma source may be coupled to the chamber to provide improved oxidation performance.

It is understood that additional temperature sensors may be added to the process chamber, and their measurements may also be used to detect radical species flux at different locations. The locations of the temperature sensor may be selected based on knowledge of where radicals may impinge within a chamber and/or an area associated with a chamber, such as at the inlet and exhaust line of the process chamber. It has been found that increased amounts of radicals may impinge at any location within a process chamber that has a bend or is angled at at least about 10°, for example, about 90°, such as a corner of the process chamber. Additionally, increased amounts of radicals may impinge at locations where there is a restriction in flow.

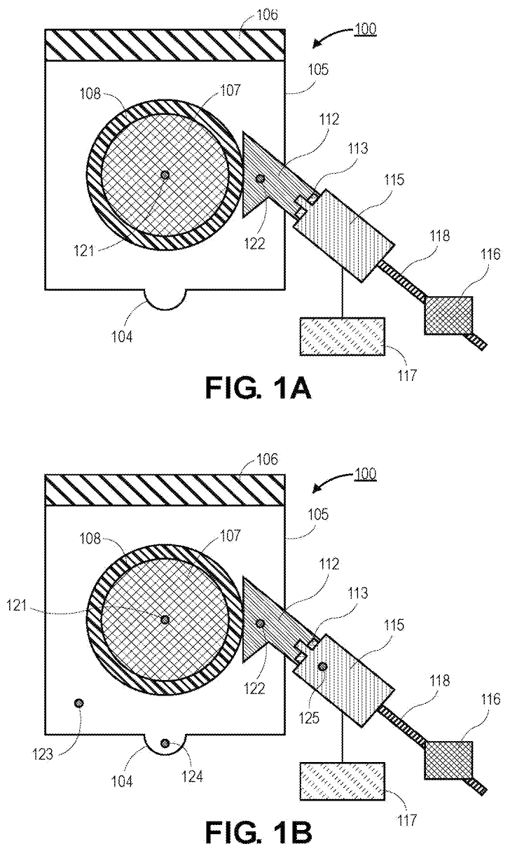

Referring now to the figures, FIG. 1A is a plan view illustration of a processing tool 100, in accordance with an embodiment. In an embodiment, the processing tool 100 may comprise a chamber 105. The chamber 105 may have any chamber configuration. For example, the chamber 105 may be suitable for low pressure environments or near atmospheric pressure environments. The chamber may be an oxidation chamber, an etch chamber, a deposition chamber, or any other type of chamber. In an embodiment, the chamber 105 may include a support for holding a substrate 107. The substrate 107 may be a semiconductor substrate, such as a silicon wafer or the like. The substrate 107 may have any suitable form factor (e.g., 200 mm, 300 mm, 450 mm, etc.). The substrate may alternatively be a glass substrate, or another type of substrate.

In one embodiment, the processing tool 100 may be a rapid thermal processing (RTP) tool. The processing tool 100 may include an array of thermal lamps (not shown) provided above (i.e., out of the plane of FIG. 1A) the substrate 107. The lamps may be suitable for rapidly increasing the temperature of the substrate 107 in order to enable thermally driven processes, such as thermal oxidation. In an embodiment, a reflector plate 108 may be provided below the substrate 107. The reflector plate 108 may reflect thermal energy back up to the substrate 107.

The chamber 105 may include additional components as well. For example, a slit valve 106 may be provided along a sidewall of the chamber 105. The slit valve 106 may be the opening through which substrate 107 is inserted and retracted from the chamber 105. In an embodiment, the chamber 105 may also include an exhaust 104. The exhaust 104 may be an outlet for removing gasses or other byproducts from the chamber 105. The exhaust 104 may include piping, pumps, and the like.

A remote plasma source (RPS) 115 may be provided as part of the semiconductor processing tool. The RPS 115 may generate a plasma outside of the chamber 105, and an adapter 112 may be fluidically coupled between the chamber and the RPS 115. The adapter 112 may be a ceramic lined stainless steel component. For example, the ceramic may include quartz or the like. In an embodiment, the RPS 115 may be controlled (at least in part) by an RPS match 117. It is to be appreciated that components such as a magnetron and generator (not shown) may also be used to control the RPS 115. The RPS match 117 may include settings for forward power, stub settings, and the like. In an embodiment, a mass flow meter (MFM) 116 may be provided along a gas line 118 that feeds the RPS 115. Additional sensors such as pressure sensors and optical sensors (not shown) may also be used to monitor performance of the RPS 115.

The RPS 115 may be coupled to the adapter 112 by a gasket 113, such as an O-ring or the like. The gasket 113 may be a wear component that degrades over use of the semiconductor processing tool 100. For example, the gasket 113 may be a common source of leaks for the semiconductor processing tool 100. Though, it is to be appreciated that other locations may generate leaks as well.

A plurality of sensors may be provided within the semiconductor processing tool 100. For example, a first sensor 121 may be provided in the chamber 105. More particularly, the first sensor 121 may be configured to detect a temperature of the reflector plate 108. The first sensor 121 may be any suitable sensor type. For example, the first sensor 121 may be a thermocouple or the like. The first sensor 121 may directly contact the reflector plate 108 in some embodiments. In some embodiments, the first sensor 121 may be located in the inlet to the process chamber 105 through which a plasma flows during the plasma-based process.

In an embodiment, the plurality of sensors may further comprise a second sensor 122 that is provided on or in the adapter 112 or in an inlet gas line (e.g., at a bend or elbow of the inlet gas line, which may or may not be proximate the process chamber 105). The second sensor 122 may also be a temperature sensor. The second sensor 122 may provide a measure of the temperature of the adapter 112 or gas line (either internally or externally). In some embodiments, the second sensor 122 may be provided on or near an exhaust line of the process chamber 105. Temperature sensors may also be positioned at other locations associated with the process chamber 105, such as at various locations within the process chamber 105, at an inlet of the process chamber, at an outlet of the process chamber, at one or more bends or other points in a gas line connected to an inlet of the process chamber, at one or more bends or other points in a gas line connected to an outlet of the process chamber, and so on.

In some embodiments, the plurality of sensors, such as first sensor 121 and second sensor 122, may be a temperature sensor. The temperature sensor may include a temperature control device, a resistance temperature device, a thermocouple, a thermistor, or a combination thereof. In some embodiments, the temperature sensor may include or be proximate to a catalytic material. The catalytic material may include stainless steel, nickel (Ni), platinum (Pt), gold (Au), or a combination thereof. The catalytic material have an increased reaction to a radical species flux, which increases a sensitivity to radical species flux.

Radical species flux refers to the flow or rate of radical species in a chemical reaction or process. Radicals are highly reactive chemical species that contain unpaired electrons. They are often involved in various chemical reactions, such as combustion, polymerization, and oxidation processes.

In a chemical reaction, radical species can be generated through different mechanisms, such as the homolytic cleavage of covalent bonds or the transfer of single electrons. Once formed, radicals can react with other molecules, initiating a chain reaction by generating new radicals.

Radical species flux is a measure of the number of radical species produced or consumed per unit time in a given reaction or process. It provides information about the dynamics and kinetics of radical reactions and is often used to study radical chain reactions. By quantifying the radical species flux, scientists can gain insights into the mechanisms, reaction rates, and overall behavior of radical-based processes.

Plasma is often associated with radical species due to its unique properties and ability to generate and sustain a high concentration of radicals. Plasma is considered the fourth state of matter, distinct from solids, liquids, and gases. It is an ionized gas consisting of a mixture of ions, electrons, neutral atoms, and molecules.

Plasmas can be generated by applying energy to a gas, causing ionization and the formation of reactive species, including radicals. The energy can be supplied through various methods such as electrical discharges, electromagnetic fields, or intense laser beams. When the energy input is sufficient, electrons are stripped from atoms or molecules, resulting in the formation of positive ions and free electrons. Collisions between these charged particles and gas molecules can lead to the production of reactive species, including radicals.

In a plasma environment, radicals can be formed through processes such as electron impact dissociation, ion-molecule reactions, or reactions involving excited species. The high energy and reactivity of the plasma environment facilitate the formation and propagation of radical species, leading to complex and often non-equilibrium chemical reactions.

Plasma-generated radicals are utilized in various applications, such as plasma chemistry, surface modification, plasma etching, and plasma polymerization. These radical species can initiate and drive chemical reactions that are otherwise challenging to achieve under normal conditions. Additionally, plasma radicals can be used for the degradation of pollutants, sterilization, and synthesis of advanced materials. The amount of radical species flux of a plasma can affect process parameters, such as etch rate, deposition rate, polymerization rate, and so on. Therefore, understanding the generation, behavior, and flux of radical species in plasma systems is useful for optimizing plasma-based processes and harnessing the unique reactivity of radicals in various applications.

In embodiments, the plurality of temperature sensors (e.g., thermocouples, RTDs, thermistors, semiconductor-based sensors, etc.) may be used in order to detect a drift or excursions of radical species flux associated with a particular process. In one embodiment, a plurality of sensors may provide temperature readings that may be compared with a value representative of a radical species flux. If the measured temperatures exceed predetermined thresholds around the value, then an indication of a drift or an excursion in radical species flux may be determined. In embodiments, the reference temperatures and the thresholds are determined through the machine learning or artificial intelligence (AI) applications that are trained on data from the temperature sensors at the respective locations on the processing tool 100. A more detailed explanation of the machine learning or AI processes are described in greater detail below.

Referring now to FIG. 1B, a plan view illustration of a processing tool 100 is shown, in accordance with an additional embodiment. In an embodiment, the processing tool 100 in FIG. 1B may be substantially similar to the processing tool 100 in FIG. 1A, with the exception of the plurality of sensors. In an embodiment, the processing tool 100 may include additional sensors to those shown in FIG. 1A. For example, a third sensor 123 may be provided within the chamber 105. The third sensor 105 may be a temperature sensor. The third sensor 123 may be used to measure a temperature of a sidewall or other surface within the chamber 105.

In an embodiment, a fourth sensor 124 may also be used in some embodiments. The fourth sensor 124 may also be a temperature sensor. As shown in FIG. 1B, the fourth sensor 124 may be located within the exhaust 104. The fourth sensor 124 may be positioned at any point within the exhaust 104 system. For example, the fourth sensor 124 may be at the entrance of the exhaust 104, at the pump, or after the pump.

In an embodiment, a fifth sensor 125 may be used as well. The fifth sensor 125 may be a temperature sensor in some embodiments. The fifth sensor 125 may be located within the RPS 115. For example, the fifth sensor 125 may measure a sidewall temperature of the chamber of the RPS 115.

While described as temperature sensors, the additional sensor 123-125 may also include other types of sensors. For example, the sensors 123-125 may include pressure sensors, optical sensors, and the like. Similar to measurements of temperature sensors, measurements from one or more other types of sensors may also be correlated with radical species flux, such as through use of machine learning.

As illustrated, a plurality of different sensor locations can be used for excursion detection of radical species flux. The inclusion of more sensors may allow for improved drift detection. That is, some portions of the semiconductor processing tool 100 may drift before other portions of the semiconductor processing tool 100, depending on the mechanism that is causing the drift. For example, if the reflector plate 108 becomes dirty or a redeposition coating is formed over the reflector plate 108, then changes to the temperature of the first sensor 121 may be an initial indicator of drift before other temperatures start to change.

It is to be appreciated that the RPS may be located at various positions relative to the chamber. For example, a top RPS setup may be used in some embodiments. In such an embodiment, the plasma enters the chamber from above. In other embodiments, a cross-flow setup may be used. In such an embodiment, the RPS is located to the side of the chamber, and the plasma flows across the chamber. While particular embodiments are shown, it is to be appreciated that any RPS configuration may be used in conjunction with embodiments described herein.

In embodiments, one or more sensors 121-125 are connected to a computing device executing one or more trained machine learning model. The trained machine model(s) may be trained to estimate values representative of a radical species flux based on sensor measurements at one or more locations, such as temperature measurements at one or more locations. A machine learning model may be trained using data from a particular sensor at a particular location and during a particular type of process. Such training may be performed using data from known steady state and/or healthy tools. In some embodiments, training is performed using different data associated with different known radical species flux. Based on the training, the machine learning model may be trained to output an accurate estimate of radical species flux based on an input temperature. Alternatively, the machine learning model may be trained to output a value that has a correlation to a radical species flux. For example, when radical species flux increases, the value may likewise increase, and when radical species flux decreases, the value may likewise decrease.

In one embodiment, one or more of the trained machine learning models is a regression model trained using regression. Examples of regression models are regression models trained using linear regression or Gaussian regression. A regression model predicts a value of Y given known values of X variables. The regression model may be trained using regression analysis, which may include interpolation and/or extrapolation. In one embodiment, parameters of the regression model are estimated using least squares. Alternatively, Bayesian linear regression, percentage regression, leas absolute deviations, nonparametric regression, scenario optimization and/or distance metric learning may be performed to train the regression model.

In one embodiment, one or more of the trained machine learning models are decision trees, random forests, support vector machines, or other types of machine learning models.

In one embodiment, one or more of the trained machine learning models is an artificial neural network (also referred to simply as a neural network). The artificial neural network may be, for example, a convolutional neural network (CNN) or a deep neural network. In one embodiment, processing logic performs supervised machine learning to train the neural network.

Artificial neural networks generally include a feature representation component with a classifier or regression layers that map features to a target output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs). The neural network may be a deep network with multiple hidden layers or a shallow network with zero or a few (e.g., 1-2) hidden layers. Deep learning is a class of machine learning algorithms that use a cascade of multiple layers of nonlinear processing units for feature extraction and transformation. Each successive layer uses the output from the previous layer as input. Neural networks may learn in a supervised (e.g., classification) and/or unsupervised (e.g., pattern analysis) manner. Some neural networks (e.g., such as deep neural networks) include a hierarchy of layers, where the different layers learn different levels of representations that correspond to different levels of abstraction. In deep learning, each level learns to transform its input data into a slightly more abstract and composite representation.

One of more of the trained machine learning models may be recurrent neural networks (RNNs). An RNN is a type of neural network that includes a memory to enable the neural network to capture temporal dependencies. An RNN is able to learn input-output mappings that depend on both a current input and past inputs. The RNN will address past and future measurements and make predictions based on this continuous measurement information. For example, sensor measurements may continually be taken during a process, and those sets of measurements may be input into the RNN sequentially. Current sensor measurements and prior sensor measurements may affect a current output of the trained machine learning model. One type of RNN that may be used is a long short term memory (LSTM) neural network.

Some trained machine learning models of the processing tool may be used for multiple different process chambers that have a common process chamber type with sensors (e.g., temperature sensors) at same locations and that are used to perform the same or similar processes. For example, a first process chamber and a second process chamber may both be etch chambers that perform a same etch process. A trained machine learning model may be used to determine when to schedule each of first process chamber and second process chamber for maintenance, when to cease a seasoning process after maintenance, and so on.

Some trained machine learning models use all sensor measurements generated by a process chamber and/or for a process chamber (e.g., for a process performed on the process chamber). Some trained machine learning models use a subset of generated sensor measurements. For example, a trained machine learning model trained to determine a seasoning recipe endpoint may receive as an input measurements from one or more temperature sensors.

In one embodiment, the trained machine learning model processes temperature sensor measurements periodically (e.g., every 50-100 milliseconds) during a process such as a plasma process. For each input, the trained machine learning model may output a value representative of a radical species flux. The method may then determine whether the value representative of the radical species flux satisfies a criterion, where a remedial action (e.g., such as maintenance or stopping of a seasoning process) may be scheduled or determined responsive to determining that the value representative of the radical species flux satisfies the criterion. In one embodiment, the machine learning model is trained to make such determinations, and rather than or in addition to outputting a value associated with radical species flux, the machine learning model outputs a recommendation, notice and/or instruction to perform a remedial action (e.g., to perform maintenance or to stop a seasoning process). The criterion may include a radical species flux drift threshold, and the criterion may be satisfied responsive to the determined value representative of radical species flux meeting or exceeding the radical species flux drift threshold. In one embodiment, the trained machine learning model is a recurrent neural network (RNN). In one embodiment, the trained machine learning model is a neural network (e.g., a CNN). In one embodiment the trained machine learning model is a linear regression model and in another embodiment the machine learning model is a Gaussian regression model. In one embodiment, the trained machine learning model is a random forest.

Training of a neural network may be achieved in a supervised learning manner, which involves feeding a training dataset consisting of labeled inputs through the network, observing its outputs, defining an error (by measuring the difference between the outputs and the label values), and using techniques such as deep gradient descent and backpropagation to tune the weights of the network across all its layers and nodes such that the error is minimized. In many applications, repeating this process across the many labeled inputs in the training dataset yields a network that can produce correct output when presented with inputs that are different than the ones present in the training dataset. In high-dimensional settings, such as large images, this generalization is achieved when a sufficiently large and diverse training dataset is made available. Training may be performed using temperature measurements measured while processing substrates when a system is in a known good state. When temperature measurements are taken during processing after the process chamber as deviated from the known good state, such deviation may be detected by the machine learning model, which may recommend performing maintenance. In some embodiments, training may be performed using a process chamber after seasoning processes are completed. After the machine learning model is trained, temperature measurements may be periodically or continuously taken and input into the machine learning model during a seasoning process, and the machine learning model may output an indication as to whether the process chamber has reached a target seasoned state. Once the machine learning model is trained, temperature measurements may be input into the machine learning model, which may output an indication of radical flux drift. For example, a value of 0 may represent a known good state of radical flux, and +/− values deviating from 0 may indicate positive or negative drift from the known good state, where the magnitude of the value may indicate an amount of drift from the known good state.

Each of the trained machine learning models of the processing tool may be periodically or continuously retrained to achieve continuous learning and improvement of the trained machine learning models in some embodiments. Each model may generate an output based on an input, an action may be performed based on the output, and a result of the action may be measured. In some instances the result of the action is measured within fractions of a second (e.g., milliseconds), seconds or minutes, and in some instances it takes longer to measure the result of the action. For example, one or more additional processes may be performed before a result of the action can be measured. The action and the result of the action may indicate whether the output was a correct output and/or a difference between what the output should have been and what the output was. Accordingly, the action and the result of the action may be used to determine a target output that can be used as a label for the sensor measurements. Once the result of the action is determined, the input (i.e., sensor measurements), the output of the trained machine learning model, and the target output of the machine learning model (or the action and the result of the action) may be used as a new training data item. The new training data item may then be used to further train the trained machine learning model.

In one embodiment, a process manager (not pictured) may be included that includes one or more trained machine learning models that have been trained to detect radical species flux, i.e. drifts in the radical species flux. Such trained machine learning models trained to detect radical species flux may be trained from a training dataset including temperature measurements (e.g., temperature sensor measurements) and labels indicating radical species flux and/or known states of process chambers, as discussed above. In one embodiment, temperature measurements provide temperatures at various locations of the process chamber, which may be correlated to values representative of the radical species flux at the various location based on being input into one or more trained machine learning models. Processing logic may identify a difference between a first and second measurement and if the difference satisfies a criterion. For example, a trained machine learning model of process manager may use temperature measurements to determine when a maintenance of the chamber should be performed.

In one embodiment, a training data item including the sensor measurements, a prediction as to whether the process chamber is ready to return to service and machine learning output as to whether the process chamber was actually ready to return to service (e.g., an indication that the process chamber passed a requalification test or did not pass a requalification test) is used to update a training of the trained machine learning model. The trained machine learning model may be retrained each time after the process chamber (or after other process chambers) is returned to service after being taken down for maintenance. Embodiments reduce the number of repetitions of a seasoning process that are performed prior to bringing a process chamber back into service after maintenance. For example, a standard process for seasoning an etch chamber may be to run 25 iterations of a seasoning process on the etch chamber, and to then perform a test process on the process chamber. However, in embodiments processing logic may determine immediately when the process chamber is ready to have a test process run rather than waiting until a full 25 iterations of the seasoning process have been completed. In some embodiments, no test process is run after the trained machine learning model has indicated that a process chamber is ready to return to service.

In one embodiment, a maintenance manager (not pictured) includes one or more trained machine learning models that have been trained to detect when maintenance should be performed on a process chamber. Such trained machine learning models trained to detect when a process chamber is due for maintenance may be trained from a training dataset including many different measurements generated by one or more process chambers during processes performed on product substrates (e.g., on product wafers). The many different measurements may include a first temperature at a first location of the process chamber, and/or a second temperature at a second location of the process chamber, and labels indicating whether or not the process chamber was due for maintenance after the process at which the combined sensor measurements were taken was complete. In an example, a first temperature sensor may be included at an inlet to the process chamber through which a plasma flows during the plasma-based process, and a second temperature sensor may be included at an exhaust line of the process chamber. Additionally, occasionally a test process may be run using a test substrate, blanket substrate (substrate with a uniform coating that is not patterned), bare substrate, sensor substrate (substrate with multiple sensors disposed thereon), etc. Sensor measurements from the process chamber (and optionally from the sensor substrate) may be generated and input into the trained machine learning model to generate an output.

Different maintenance prediction machine learning models may be trained for each process chamber and/or for each pair of a process chamber and a process or set of processes performed on that process chamber. Once the trained machine learning model is employed, sensor measurements may be periodically or continuously generated by one or multiple sensors of a process chamber (and/or sensor substrate) during a product process and/or an occasional test process. These measurements may be processed by a trained machine learning model of maintenance manager to determine when a drift in radical species flux has occurred and thus when the process chamber warrants maintenance, and when the process chamber should be taken down for maintenance. Examples of maintenance include cleaning the process chamber, replacing one or more parts of the process chamber, replacing an RPS unit, replacing one or more components of an RPS unit, changing one or more settings of a plasma source, and so on. In embodiments, the maintenance prediction machine learning models identify a type of maintenance that should be performed on the process chamber and/or plasma source based on the sensor measurements. For example, a trained machine learning model may indicate that a process chamber should be cleaned, that a protective liner should be replaced, that a process kit ring should be replaced, that a showerhead should be replaced, that a plasma source should be replaced, and so on.

After a process chamber has been marked as due for being serviced, a technician may determine whether the process chamber actually should be serviced and/or a type of maintenance that should be performed on the process chamber. In one embodiment, a training data item including the sensor measurements, a prediction as to whether the process chamber is due for maintenance (and/or a type of maintenance to be performed) and an indication as to whether maintenance was actually warranted for the process chamber is used to update a training of the trained machine learning model. The trained machine learning model may be retrained each time after the process chamber (or after other process chambers) is scheduled for maintenance. Alternatively, or additionally, the machine learning model may be continuously or periodically retrained using data points associated with substrates processed by a process chamber, where the data points include sensor measurements, differences between a value representative of a radical species flux associated with plasma-based process based on temperature whether maintenance should have been performed or when a seasoning process should be performed after a maintenance event is complete. Embodiments reduce the number of substrates that get processed by a process chamber that needs to be serviced, and additionally ensures that process chambers are not serviced more frequently than is called for.

In various embodiments, the server may be and/or include a computing device such as a personal computer, a server computer, a programmable logic controller (PLC), a microcontroller, and so on. The server may include (or be) one or more processing devices, which may be general-purpose processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like. The server may include a data storage device (e.g., one or more disk drives and/or solid state drives), a main memory, a static memory, a network interface, and/or other components. The processing device of the server may execute instructions to train machine learning models and to send the trained machine learning models to platform controllers and/or to controllers of individual tools (e.g., controllers of process chambers) in embodiments. The instructions may be stored on a computer readable storage medium, which may include the main memory, static memory, secondary storage and/or processing device (during execution of the instructions).

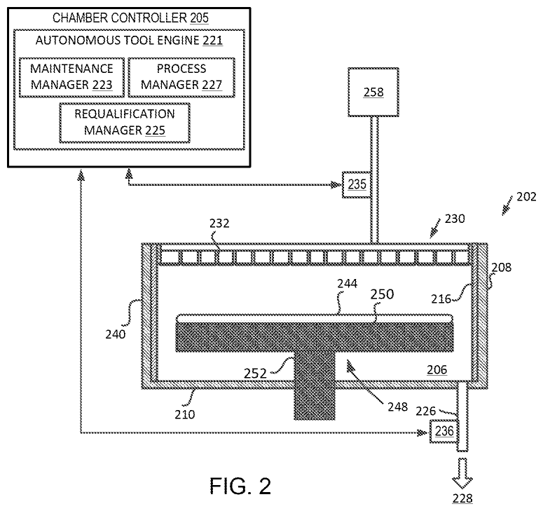

FIG. 2 is a sectional view of a processing tool 200 including a process chamber 202 and a chamber controller 205 operatively connected to the process chamber 202. Chamber controller 205 may be mounted to the process chamber 202, or may be disposed near the process chamber (e.g., connected to another component of a substrate processing system). The process chamber 202 may be an etch process chamber, a deposition chamber, an anneal chamber, or other type of process chamber used to process substrates (e.g., wafers) such as semiconductor substrates via a plasma-based process. For example, the processing chamber 202 may be a chamber for a plasma etcher or plasma etch reactor, a plasma cleaner, a CVD or ALD reactor (e.g., such as a plasma enhanced CVD or ALD reactor), an ion assisted deposition (IAD) chamber, a physical vapor deposition (PVD) chamber, and so forth.

In one embodiment, the processing chamber 202 includes a chamber body and a showerhead 230 that encloses an interior volume 206. The showerhead 230 may include a showerhead base and a showerhead gas distribution plate. Alternatively, the showerhead 230 may be replaced by a lid and a nozzle in some embodiments, or by multiple pie shaped showerhead compartments and plasma generation units in other embodiments. The chamber body may be fabricated from aluminum, stainless steel or other suitable material such as titanium (Ti). The chamber body generally includes sidewalls 208 and a bottom 210. A liner 216 may be disposed adjacent the sidewalls 208 to protect the chamber body.

An exhaust port 226 may be defined in the chamber body, and may couple the interior volume 206 to a pump system 228. The pump system 228 may include one or more pumps and throttle valves utilized to evacuate and regulate the pressure of the interior volume 206 of the processing chamber 202.

The showerhead 230 (or lid) may be supported on the sidewalls 208 of the chamber body. The showerhead 230 (or lid) may be opened to allow access to the interior volume 206 of the processing chamber 202, and may provide a seal for the processing chamber 202 while closed. A remote plasma source 258 may be coupled to the processing chamber 202 to provide process and/or cleaning gases and/or a remote plasma to the interior volume 206 through the showerhead 230 or lid and nozzle. Showerhead 230 may be used for processing chambers used for dielectric etch (etching of dielectric materials). The showerhead 230 may include a gas distribution plate (GDP) and may have multiple gas delivery holes 232 throughout the GDP. The showerhead 230 may include the GDP bonded to an aluminum base or an anodized aluminum base. The GDP may be made from Si or SiC, or may be a ceramic which is coated with Y₂O₃, Al₂O₃, Y₃Al₅O₁₂ (YAG), and so forth.

Examples of processing gases that may be used to process substrates in the processing chamber 202 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases).

A heater assembly 248 may be disposed in the interior volume 206 of the processing chamber 202 below the showerhead 230 or lid. The heater assembly 248 includes a support 250 that holds a substrate 244 during processing. The support 250 is attached to the end of a shaft 252 that is coupled to the chamber body via a flange. The support 250, shaft 252 and flange may be constructed of a material containing AlN, for example. The support 250 may further include mesas (e.g., dimples or bumps). The support may additionally include wires, for example, tungsten wires (not shown), embedded within the heater material of the support 250. In one embodiment, the support 250 may include metallic heater and sensor layers that are sandwiched between AlN ceramic layers. Such an assembly may be sintered in a high-temperature furnace to create a monolithic assembly. The layers may include a combination of heater circuits, sensor elements, ground planes, radio frequency grids and metallic and ceramic flow channels.

Exemplary chamber components of the process chamber 202 include, without limitations, an electrostatic chuck, a nozzle, a gas distribution plate, a shower head (e.g., 230), an electrostatic chuck component, a chamber wall (e.g., 208), a liner (e.g., 216), a liner kit, a gas line, a chamber lid, a nozzle, a single ring, a processing kit ring, edge ring, a base, a shield, a plasma screen, a flow equalizer, a cooling base, a chamber viewport, a bellow, any part of a heater assembly (including the support 250, the shaft 252, the flange), faceplate, blocker plate, and so on.

In embodiments, process chamber includes many different sensors, including temperature sensors 235-236. The sensors may additionally or alternatively include optical sensors, such as optical emission spectrometer and/or reflectometer, pressure sensors, power sensors, other electrical sensors, flow rate sensors, and so on. Some sensors 235-236 may be internal to the process chamber 202, while other sensors 235-236 may be external to the process chamber 202 and measure the flow and/or delivery of gases, power, etc. to the process chamber 230. In one embodiment, the sensor 235 may be located at the inlet of the process chamber and a temperature sensor 236 located at the exhaust of the process chamber.

Chamber controller 205 may be configured to perform operations for one or a few process chambers (e.g., for process chamber 202), or on a platform (e.g., tool cluster) that contains multiple chambers. For example, chamber controller 205 may be configured to control etch chambers of a cluster tool, or etch chambers that perform a particular etch process. In embodiments, chamber controller 205 includes an autonomous tool engine 221, which may include a maintenance manager 223, a requalification manager 225 and/or a process manager 227. For a single platform with multiple process chambers attached thereto, each of the process chamber may include its own dedicated chamber controller 205. Alternatively, some of the process chambers attached to a cluster tool or mainframe may share a common chamber controller. In one embodiment, chamber controller 205 is not used, and instead a platform controller is used to control all of the process chambers attached to a cluster tool.

In some embodiments, autonomous tool engine 221 uses sensor measurements (e.g., temperature sensor measurements) from one or more of sensors 235-236 to make decisions with respect to process chamber 202. Chamber controller 205 may determine, for example, whether maintenance is due for process chamber 202, a type of maintenance to be performed on process chamber 202, whether process chamber 202 is ready to be brought back into service after undergoing maintenance and seasoning, and so on using autonomous tool engine 221. In embodiments, maintenance manager 223, process manager 227 and/or requalification manager 225 may include one or more trained machine learning models that have been trained to receive sensor measurements (e.g., temperature measurements) and to make determinations with regards to radical species flux. Such determinations may be an estimation of a radical species flux, an estimation of an amount of drift of radical species flux from a radical species flux of a process chamber known to be in a good condition, an estimation of whether to perform maintenance, an estimation of whether to stop a seasoning process, and so on.

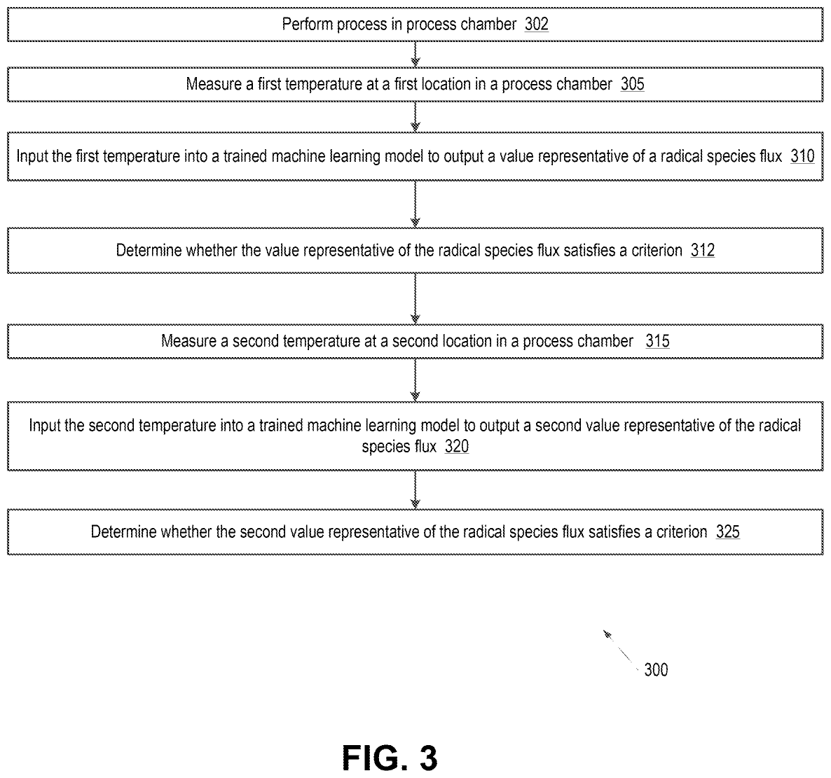

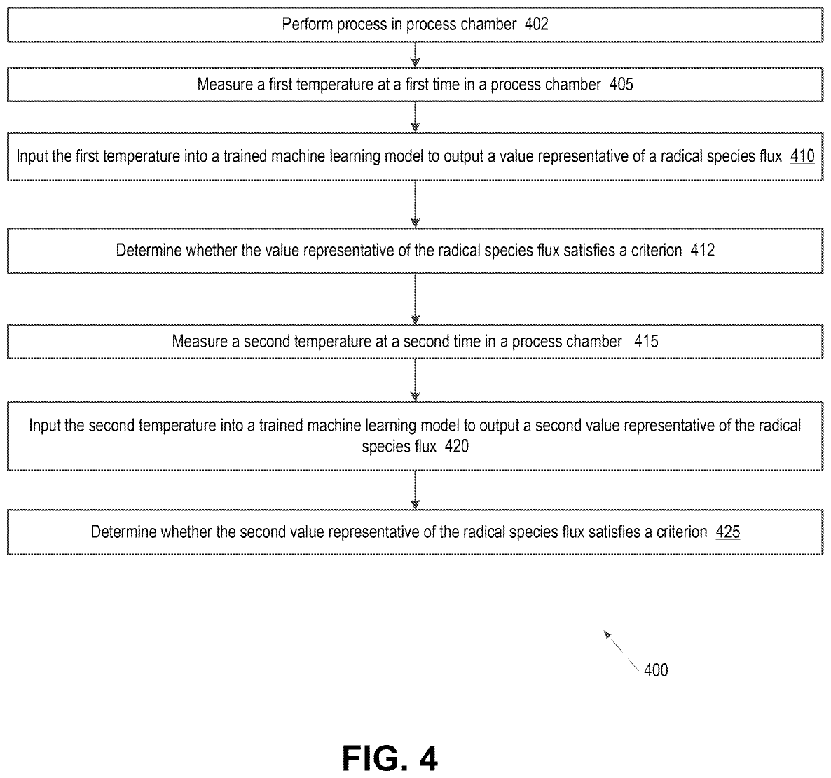

FIGS. 3-4 are flow charts for methods of training machine learning models and/or using trained machine learning models to make decisions for process chambers based on temperature sensor measurements, according to embodiments. The methods may be performed with the components described with reference to FIGS. 1-2, as will be apparent. For example, methods may be performed by a chamber controller 205 in embodiments. At least some operations of the methods may be performed by a processing logic that may comprise hardware (e.g., circuitry, dedicated logic, programmable logic, microcode, etc.), software (e.g., instructions run on a processing device to perform hardware simulation), or a combination thereof. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are performed in every embodiment. Other process flows are possible.

FIG. 3 is a flow chart for a method 300 of performing actions by a process tool and/or substrate processing system, according to an embodiment. At block 302 of method 300, processing logic causes a processing chamber to perform a process, such as an etch process, a deposition process, a plasma-based process, or a seasoning process. At block 305, processing logic receives a first measurement from a temperature sensor at a first location associated with the process chamber during and/or after the process, such as a plasma-based process. In some embodiments, the first location may include an inlet to the process chamber through which a plasma flows during the plasma-based process. In some embodiments, the temperature may be measured during a plasma-based process at a first time and at a second time. In one embodiment, the plasma-based process may include a seasoning process for the process chamber. In another embodiment, the process may include a different plasma-based process. A second value representative of a second radical species flux based on the second temperature may be determined. The second value to the first value at the first location may be compared to identify a difference between the second value and the first value. The method may further include determining whether the difference satisfies a criterion and stopping the seasoning process responsive to determining that the difference satisfies the criterion. In an embodiment, if the difference satisfies a criterion, maintenance may be scheduled.

At block 310, the first temperature measurement is inputted into at trained machine learning model to determine and output a value representative of the radical species flux. In one embodiment, the value indicates an amount of drift in radical species flux from a known good condition. A magnitude of the value may indicate an amount of drift. Additionally, or alternatively, the machine learning model may output an indication to perform one or more actions, such as a maintenance action, an action associated with a seasoning process (e.g., stopping or continuing the seasoning process), and so on. At block 312, processing logic may determine whether the value representative of the radical species flux satisfies a criterion. The criterion may be a threshold. If the value meets or exceeds the threshold, then an action such as a maintenance action may be recommended, scheduled or initiated. In one embodiment, rather than or in addition to outputting a value representative of a radical species flux, the machine learning model may output an estimate of when a radical species flux drift will reach a threshold amount that should be addressed through maintenance. Accordingly, the machine learning model may output a recommendation to perform a scheduled maintenance at a designated future time. In one embodiment, the machine learning model outputs a recommendation to perform one or more remedial actions presently, such as to perform maintenance.

In one embodiment, at block 315, processing logic receives a second measurement from a second temperature sensor at a second location in a process chamber. The second location may include an exhaust line of the process chamber. At block 320, the second temperature measurement is inputted into the trained machine learning model or a different trained machine learning model to determine and output a second value representation species flux and/or any of the other types of outputs discussed above. The output in block 310 and 320, i.e. value representative of the radical species flux, may indicate as to whether the process chamber should be scheduled for maintenance or an indication as to whether the process chamber should be returned to service. The trained machine learning model(s) may have been trained as set forth herein above, and may correspond to any of the trained machine learning models set forth herein above.

In one embodiment, at block 325, processing logic determines that the output satisfies a criterion. The criterion may include a radical species flux drift threshold, a yes/no criterion, or some other criterion. In the case of a trained machine learning model trained to detect a value representative of the radical species flux, the criterion may be a radical species flux drift threshold, and the criterion may be satisfied if the difference between a first value representative and the second value representative meets or exceeds the radical species flux drift threshold. In one embodiment, the trained machine learning model outputs a yes or a no, where a yes indicates that an radical species flux drift threshold has been reached and a no indicates that the radical species flux drift threshold has not yet been reached. In one embodiment, the trained machine learning model outputs a yes or a no, where a yes indicates that maintenance should be performed on the process chamber. These operations may additionally or alternatively be performed at block 312.

The amount of drift may be correlated to a drift index. The drift index may be a value between 0 and 1. When there is no drift, the drift index is at 0, and as drift increases the drift index increases toward 1. In some embodiments, the temperature ranges may correlate to a drift index that is up to approximately 0.4, up to approximately 0.3, or up to approximately 0.2, depending on the robustness of the given process.

In one embodiment, the trained machine learning model outputs multiple maintenance classifications, and for each maintenance classification the trained machine learning model provides a yes indicating that the type of maintenance associated with that maintenance classification should be performed or a no indicating that the type of maintenance associated with that maintenance classification need not be performed. Examples of maintenance classifications include scheduled cleaning, part replacement for a first part, part replacement for a second part, and so on. In one embodiment, the trained machine learning model outputs a yes or a no, where a yes indicates that no more seasoning is warranted for the process chamber (and that the process chamber is ready to return to service) and no indicates that one or more seasoning processes should still be performed on the process chamber (and that the process chamber is not ready to return to service).

FIG. 4 is a flow chart for a method 400 of performing actions by a process tool and/or substrate processing system, according to an embodiment. At block 402 of method 400, processing logic causes a processing chamber to perform a process, such as an etch process, a deposition process, a plasma-based process, or a seasoning process. At block 405, processing logic receives a first measurement from a temperature sensor at a first time. The temperature sensor is placed in a location associated with the process chamber during and/or after the process, such as a plasma-based process. In some embodiments, the location may include an inlet to the process chamber through which a plasma flows during the plasma-based process In some embodiments, the location may include an exhaust line of the process chamber. In some embodiments, the plasma-based process may include a seasoning process for the process chamber, or a different-plasma based process.

At block 410, the first temperature measurement is inputted into at trained machine learning model to determine and output a value representative of the radical species flux. In one embodiment, the value indicates an amount of drift in radical species flux from a known good condition. A magnitude of the value may indicate an amount of drift. Additionally, or alternatively, the machine learning model may output an indication to perform one or more actions, such as a maintenance action, an action associated with a seasoning process (e.g., stopping or continuing the seasoning process), and so on. At block 412, processing logic may determine whether the value representative of the radical species flux satisfies a criterion. The criterion may be a threshold. If the value meets or exceeds the threshold, then an action such as a maintenance action may be recommended, scheduled or initiated. In one embodiment, rather than or in addition to outputting a value representative of a radical species flux, the machine learning model may output an estimate of when a radical species flux drift will reach a threshold amount that should be addressed through maintenance. Accordingly, the machine learning model may output a recommendation to perform a scheduled maintenance at a designated future time. In one embodiment, the machine learning model outputs a recommendation to perform one or more remedial actions presently, such as to perform maintenance.

In one embodiment, at block 415, processing logic receives a second measurement from a second temperature sensor at a second time in a process chamber. At block 420, the second temperature measurement is inputted into the trained machine learning model or a different trained machine learning model to determine and output a second value representation species flux and/or any of the other types of outputs discussed above. The output in block 410 and 420, i.e. value representative of the radical species flux, may indicate as to whether the process chamber should be scheduled for maintenance or an indication as to whether the process chamber should be returned to service. The trained machine learning model(s) may have been trained as set forth herein above, and may correspond to any of the trained machine learning models set forth herein above.

In one embodiment, at block 425, processing logic determines that the output satisfies a criterion. The criterion may include a radical species flux drift threshold, a yes/no criterion, or some other criterion. In the case of a trained machine learning model trained to detect a value representative of the radical species flux, the criterion may be a radical species flux drift threshold, and the criterion may be satisfied if the difference between a first value representative and the second value representative meets or exceeds the radical species flux drift threshold. In one embodiment, the trained machine learning model outputs a yes or a no, where a yes indicates that an radical species flux drift threshold has been reached and a no indicates that the radical species flux drift threshold has not yet been reached. In one embodiment, the trained machine learning model outputs a yes or a no, where a yes indicates that maintenance should be performed on the process chamber. These operations may additionally or alternatively be performed at block 412.

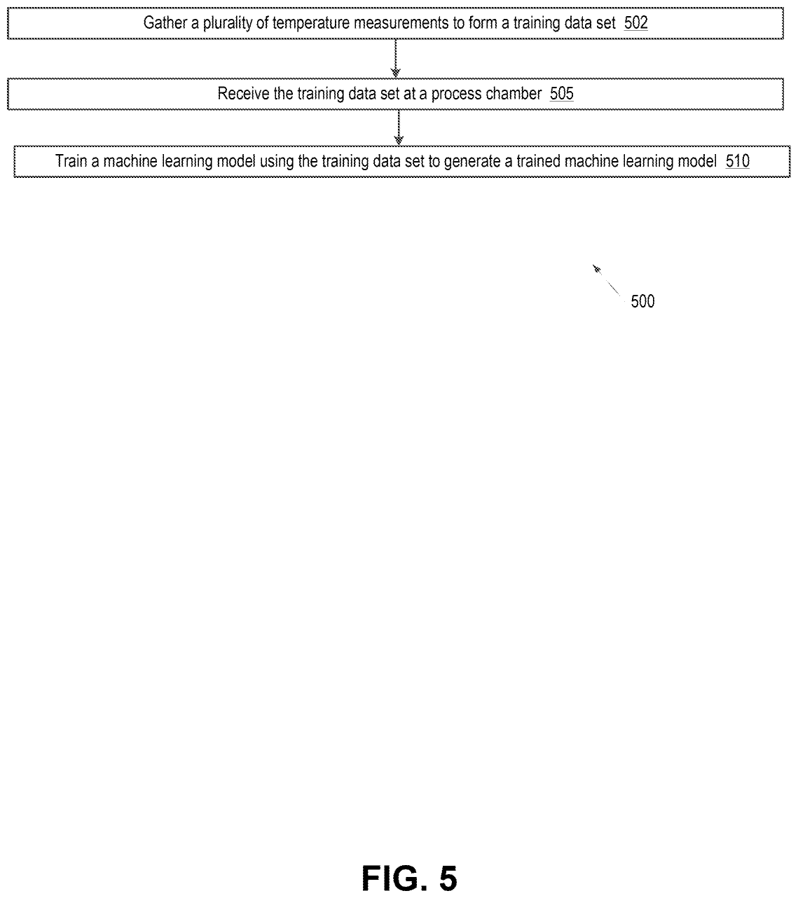

FIG. 5 is a flow chart for a method 400 of training a machine learning model according to an embodiment. In an embodiment, the method of training 500 may be performed to monitor a semiconductor process tool, such as an RTP tool with an RPS. At block 502 of method 500, a plurality of temperature measurements is gathered to form a training data set. In some embodiments, the training data set includes a plurality of data items, wherein each data item may include a temperature measurement generated by a temperature sensor at a location associated with the process chamber and a label indicating a state of the process chamber (e.g., whether or not the process chamber was in a known good state). At block 405, the processing logic receives the training data set at a process chamber.

At block 510, a machine learning model is trained using the training data set of block 502 to generate a trained machine learning model. The trained machine learning model is trained to receive a temperature measurement generated by the temperature sensor at the location and to determine a value representative of a radical species flux associated with the plasma-based process based on temperature. The machine learning model of block 510 may be further trained to predict when a seasoning process performed on the process chamber after a maintenance event is complete based on temperature. In another embodiment, the machine learning model of block 510 may be further trained to predict when to perform maintenance associate with the process chamber based on the temperature.

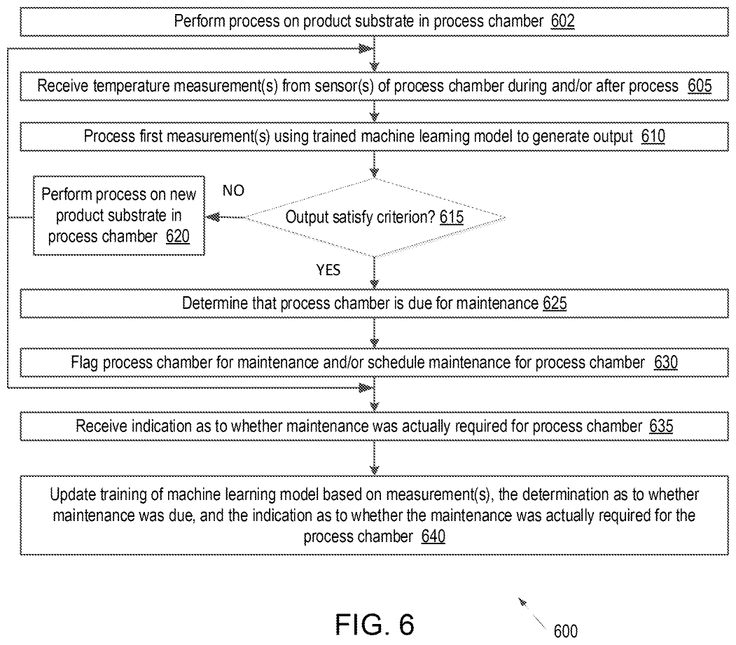

FIG. 6 is a flow chart for a method 600 of automatically determining when to perform maintenance on a process chamber, according to an embodiment. At block 602 of method 600, processing logic initiates a process on a product substrate in a chamber. The process may be an etch process, a deposition process, an plasma-based process, or some other process, for example. The process may be performed on a product substrate having one or more films thereon and/or may be performed to treat a substrate thereon. At block 605, processing logic receives one or more measurements from a set of sensors of the process chamber during and/or after the process. The measurements may be, for example, temperature measurements taken at locations at which heightened radical flux is known to occur. At block 610, processing logic processes the measurements using a trained machine learning model that has been trained to determine whether maintenance should be performed on the process chamber. The trained machine learning model may have been trained to generate an output that indicates a value representative of radical species flux and/or an output that indicates whether maintenance is due and/or a type of maintenance to be performed.

At block 615, processing logic determines whether the output of the trained machine learning model satisfies a criterion. In one embodiment, processing logic compares an output value representative of radical species flux with a radical species flux drift threshold. If the value representative of radical species flux is above or meets the radical species flux drift threshold, then processing logic may determine that the output satisfies the criterion. If the value representative of radical species flux is below the radical species flux drift threshold, then the criterion may not be satisfied. In one embodiment, the output of the trained machine learning model is a yes/no indication as to whether maintenance should be performed. If the output is a yes, that maintenance should be performed (or that a particular type of maintenance should be performed), the criterion is satisfied. If the output is a no, that maintenance should not be performed, then the criterion is not satisfied. If the criterion is not satisfied, the method continues to block 620. If the criterion is satisfied, the method proceeds to block 625.

At block 620, processing logic initiates the process on a new substrate (after causing a robot arm to remove the first substrate from the process chamber and to insert the new substrate into the process chamber). The method then returns to block 605 and sensor measurements associated with performance of the process on the new substrate are received. Additionally, the method may proceed to block 635.

At block 625, processing logic determines that the process chamber is due for maintenance. At block 630, processing logic may flag the process chamber for maintenance (e.g., a cleaning) and/or may actively schedule a cleaning for the process chamber. At block 635, processing logic may receive an indication as to whether maintenance was actually performed on the process chamber. Processing logic may additionally or alternatively receive an indication as to a state of the process chamber and/or critical dimension measurements of product substrates processed by the process chamber at block 602 and/or block 620. At block 640, processing logic may update the training of the machine learning model based on the measurements received at block 605, the output from block 610 indicating whether maintenance should be performed, and at least one of the indication as to whether maintenance was performed and/or a difference between measured critical dimension(s) and the target critical dimension(s) of radical species flux at locations of the process chamber. Accordingly, continuous learning may be performed to continuously update and improve the trained machine learning model. The retraining of the trained machine learning model may be performed on-tool on a controller at which the trained machine learning model is deployed in embodiments.

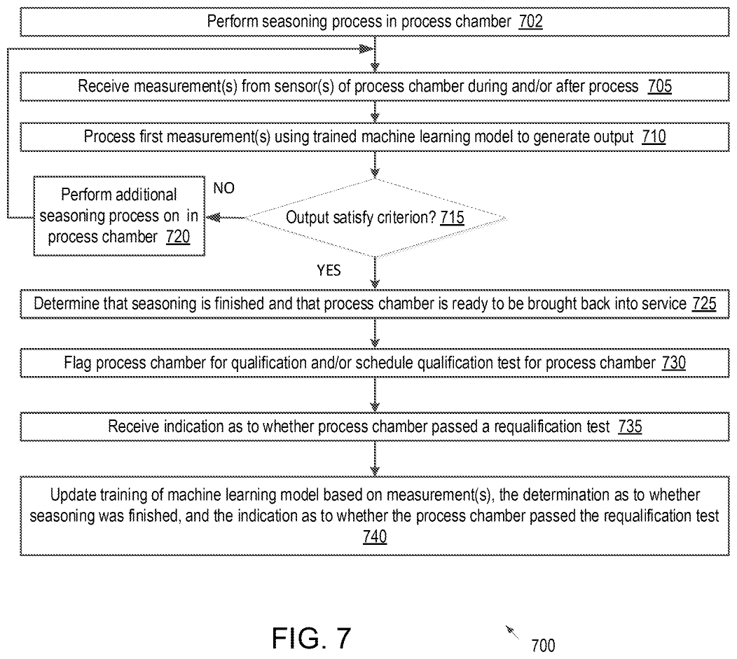

FIG. 7 is a flow chart for a method 700 of automatically determining when to return a process chamber back to service after maintenance has been performed, according to an embodiment. At block 702 of method 700, processing logic initiates a seasoning process in a chamber. The seasoning process is a chamber conditioning process that causes a state of the process chamber to reach a known state. Proper seasoning or conditioning of a process chamber after maintenance (e.g., after a part replacement and/or after a cleaning process such as a wet clean process or a dry clean process) improves wafer-to-wafer process repeatability. In one embodiment, the seasoning process cause passivation of reactor surfaces by plasma generated species, which can change the reactive sticking coefficients of radicals. Chamber seasoning may be performed to ensure that critical dimensions of devices are consistently reproduced by enabling a uniform plasma with the same ion density, electron temperature, and fluxes to be repeated wafer-to-wafer. The process may be performed on a blanket substrate, bare substrate, test substrate, etc.

At block 705, processing logic receives one or more measurements from a set of sensors of the process chamber during and/or after the process. At block 710, processing logic processes the measurements using a trained machine learning model that has been trained to determine whether seasoning is complete and/or whether a process chamber is ready to be returned to service. The trained machine learning model may have been trained to generate an output that indicates an estimated a value representative of radical species flux and/or an output that indicates whether seasoning is complete (and that the process chamber can be returned to service).

At block 715, processing logic determines whether the output of the trained machine learning model satisfies a criterion. In one embodiment, processing logic compares an output estimated value representative of radical species flux with a threshold. If the estimated value representative of radical species flux is at or above the radical threshold, then processing logic may determine that the output satisfies the criterion. If the estimated value representative of radical species flux is below the r threshold, then the criterion may not be satisfied. In one embodiment, the output of the trained machine learning model is a yes/no indication as to whether seasoning is complete. If the output is a no, that seasoning is not complete, the criterion is not satisfied. If the output is a yes, that seasoning is complete, then the criterion is satisfied. If the criterion is not satisfied, the method continues to block 720. If the criterion is satisfied, the method proceeds to block 725.

At block 720, processing logic initiates another iteration of the seasoning process and/or continues the seasoning process, optionally on a new substrate (after causing a robot arm to remove the first substrate from the process chamber and to insert the new substrate into the process chamber). The method then returns to block 705 and sensor measurements associated with performance of the process on the new substrate are received.

At block 725, processing logic determines that the process chamber is ready to be requalified and/or is ready to return to service (to be used on product substrates). At block 730, processing logic may flag the process chamber for qualification and/or may schedule a requalification process. At block 735, processing logic may receive an indication as to whether the process chamber passed the requalification test. The indication may include one or more measurement results of one or more test substrate that was processed using a test recipe or test process. In one embodiment, a blanket wafer etch process is performed on a blanket wafer, a patterned wafer etch process is performed on a patterned wafer and/or a particle test process is performed on a particle wafer (e.g., which may be a blank wafer or a blanket wafer). From the blanket wafer etch process a mean blanket wafer etch rate and a blanket wafer etch uniformity may be measured. From the patterned wafer etch process a mean patterned wafer etch rate and a patterned wafer etch uniformity may be measured. After the particle test, particles may be counted on the particle wafer. The measurement results may include, for example, an on-wafer particle count, metal contamination, film thickness, film composition, blanket wafer etch rate, blanket wafer etch uniformity, patterned wafer etch rate, patterned wafer etch uniformity, and so on. Processing logic may additionally or alternatively receive an indication as to a state of the process chamber. An actual value representative of radical species flux may be determined for the process chamber based on the measurement results.

At block 740, processing logic may update the training of the machine learning model based on the measurements received at block 605, the output from block 610 indicating whether maintenance should be performed, and the indication as to whether the process chamber passed requalification tests and/or results of requalification tests. Accordingly, continuous learning may be performed to continuously update and improve the trained machine learning model. The retraining of the trained machine learning model may be performed on-tool on a controller at which the trained machine learning model is deployed in embodiments.

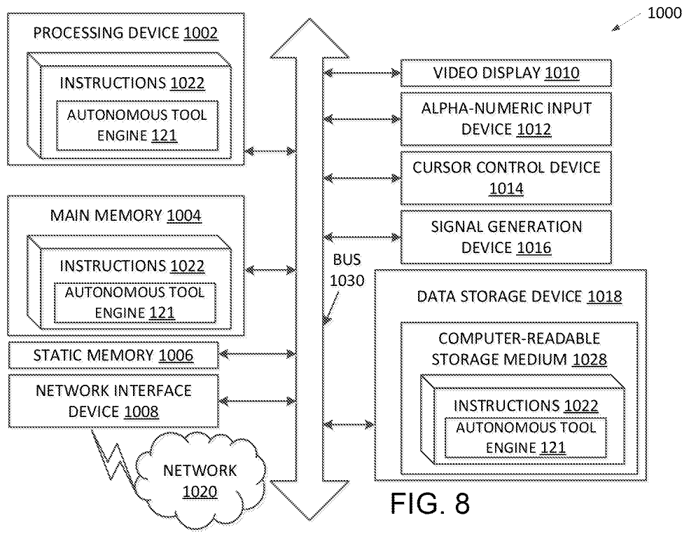

FIG. 8 illustrates a diagrammatic representation of a machine in the example form of a computing device 1000 within which a set of instructions, for causing the machine to perform any one or more of the methodologies discussed herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The example computing device 1000 includes a processing device 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), hard disk (magnetic storage) etc.), and a secondary memory (e.g., a data storage device 1018), which communicate with each other via a bus 1030.

Processing device 1002 represents one or more general-purpose processors such as a microprocessor, central processing unit, or the like. More particularly, the processing device 1002 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 1002 may also be one or more special-purpose processing devices such as an application specific integrated circuit (ASIC), a field programmable gate array (FPGA), a digital signal processor (DSP), network processor, or the like. Processing device 1002 is configured to execute the processing logic (instructions 1022) for performing the operations and steps discussed herein.

The computing device 1000 may further include a network interface device 1008. The computing device 1000 also may include a video display unit 1010 (e.g., a liquid crystal display (LCD) or a cathode ray tube (CRT)), an alphanumeric input device 1012 (e.g., a keyboard), a cursor control device 1014 (e.g., a mouse), and a signal generation device 1016 (e.g., a speaker).

The data storage device 1018 may include a machine-readable storage medium (or more specifically a computer-readable storage medium) 1028 on which is stored one or more sets of instructions 1022 embodying any one or more of the methodologies or functions described herein. The instructions 1022 may also reside, completely or at least partially, within the main memory 1004 and/or within the processing device 1002 during execution thereof by the computer system 1000, the main memory 1004 and the processing device 1002 also constituting computer-readable storage media.

The computer-readable storage medium 1028 may also be used to store an autonomous tool engine 121, and/or a software library containing methods that call an autonomous tool engine 121. While the computer-readable storage medium 1028 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies described herein. The term “computer-readable storage medium” shall accordingly be taken to include, but not be limited to, non-transitory computer readable media such as solid-state memories, and optical and magnetic media.

The modules, components and other features described herein (for example in relation to FIGS. 1A, 1B and 2) can be implemented as discrete hardware components or integrated in the functionality of hardware components such as ASICS, FPGAs, DSPs or similar devices. In addition, the modules can be implemented as firmware or functional circuitry within hardware devices. Further, the modules can be implemented in any combination of hardware devices and software components, or only in software.

Some portions of the detailed description have been presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a target result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “receiving”, “identifying”, “determining”, “selecting”, “providing”, “storing”, or the like, refer to the actions and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments of the present invention also relate to an apparatus for performing the operations herein. This apparatus may be specially constructed for the discussed purposes, or it may comprise a general purpose computer system selectively programmed by a computer program stored in the computer system. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of operations of each method may be altered so that certain operations may be performed in an inverse order so that certain operations may be performed, at least in part, concurrently with other operations. In another embodiment, instructions or sub-operations of distinct operations may be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method comprising:
measuring a first temperature at a first location associated with a process chamber during a plasma-based process; and
determining a value representative of a first radical species flux associated with the plasma-based process based on the first temperature.

2. The method of claim 1, wherein the first location comprises an inlet to the process chamber through which a plasma flows during the plasma-based process.

3. The method of claim 1, wherein determining the value representative of the radical species flux comprises inputting the temperature into a trained machine learning model that outputs the value representative of the radical species flux.

4. The method of claim 1, further comprising:
measuring a second temperature at a second location associated with the process chamber during the plasma-based process; and
determining a second value representative of a second radical species flux associated with the plasma-based process based on the second temperature.

5. The method of claim 1, wherein the second location comprises an exhaust line of the process chamber.

6. The method of claim 1, further comprising:
determining whether the determined value representative of the radical species flux satisfies a criterion; and
scheduling maintenance responsive to determining that the value representative of the radical species flux satisfies the criterion.

7. The method of claim 1, wherein measuring the temperature is performed at a first time, the method further comprising:
measuring a second temperature at the first location during the plasma-based process at a second time, wherein the plasma-based process comprises a seasoning process for the process chamber;
determining a second value representative of a second radical species flux based on the second temperature;
comparing the second value to the first value to identify a difference between the second value and the first value;
determining whether the difference between the second value and the first value satisfies a criterion; and
stopping the seasoning process responsive to determining that the difference satisfies the criterion.

8. The method of claim 1, wherein measuring the temperature is performed at a first time, the method further comprising:
measuring a second temperature at the first location during a second plasma-based process at a second time, wherein the second plasma-based process is a same process as the plasma-based process;
determining a second value representative of a second radical species flux based on the second temperature;
comparing the second value to the first value to identify a difference between the second value and the first value;
determining whether the difference between the second value and the first value satisfies a criterion; and
scheduling maintenance responsive to determining that the difference satisfies the criterion.

9. The method of claim 8, wherein the criterion comprises a radical species flux drift threshold, and wherein the criterion is satisfied responsive to the difference meeting or exceeding the radical species flux drift threshold.

10. A method comprising:
receiving a training data set associated with a plasma-based process performed at a process chamber, the training data set comprising a plurality of data items, wherein each data item of the plurality of training data items comprises a temperature measurement generated by a temperature sensor at a location associated with the process chamber and a label indicating a state of the process chamber; and
training a machine learning model using the training data set to generate a trained machine learning model trained to receive a temperature measurement generated by the temperature sensor at the location and to determine a value representative of a radical species flux associated with the plasma-based process based on the temperature.

11. The method of claim 10, wherein the machine learning model is further trained to predict when a seasoning process performed on the process chamber after a maintenance event is complete based on the temperature.

12. The method of claim 10, wherein the machine learning model is further trained to predict when to perform maintenance associated with the process chamber based on the temperature.

13. A system comprising:
a process chamber configured to perform a plasma-based process;
a temperature sensor at a first location associated with the process chamber, the temperature sensor to generate one or more temperature measurements during the plasma-based process; and
a computing device, wherein the computing device is configured to:
receive a first temperature measurement generated by the temperature sensor during the plasma-based process; and
determine a value representative of a first radical species flux associated with the plasma-based process based on the first temperature.

14. The system of claim 13, wherein the first location comprises an inlet to the process chamber through which a plasma flows during the plasma-based process.

15. The system of claim 13, wherein to determine the value representative of the radical species flux the computing device is to input the temperature into a trained machine learning model that outputs the value representative of the radical species flux.

16. The system of claim 13, further comprising:
a second temperature sensor at a second location associated with the process chamber, the second temperature sensor to generate one or more additional temperature measurements during the plasma-based process;
wherein the computing device is further configured to:
receive the second temperature measurement; and
determine a second value representative of a second radical species flux associated with the plasma-based process based on the second temperature measurement.

17. The system of claim 16, wherein the second location comprises an exhaust line of the process chamber.

18. The system of claim 13, wherein the computing device is further configured to:
determine whether the determined value representative of the radical species flux satisfies a criterion; and
schedule maintenance responsive to determining that the value representative of the radical species flux satisfies the criterion.

19. The system of claim 13, wherein the measuring of the temperature is to be performed at a first time, the computing device being further configured to:
receive a second temperature measurement generated by the temperature sensor at a second time, wherein the plasma-based process comprises a seasoning process for the process chamber;
determine a second value representative of a second radical species flux based on the second temperature;
compare the second value to the first value to identify a difference between the second value and the first value;
determine whether the difference between the second value and the first value satisfies a criterion; and
stop the seasoning process responsive to determining that the difference satisfies the criterion.

20. The system of claim 13, wherein the measuring of the temperature is to be performed at a first time, the computing device being further configured to:
receive a second temperature measurement generated by the temperature sensor at a second time, wherein the second plasma-based process is a same process as the plasma-based process;
determine a second value representative of a second radical species flux based on the second temperature;
compare the second value to the first value to identify a difference between the second value and the first value;
determine whether the difference between the second value and the first value satisfies a criterion; and
schedule maintenance responsive to determining that the difference satisfies the criterion.

21. A non-transitory computer-readable medium comprising instructions that, when executed by a processor, cause the processor to perform operations including:
measuring a first temperature at a first location associated with a process chamber during a plasma-based process; and
determining a value representative of a first radical species flux associated with the plasma-based process based on the first temperature.
